(19) United States
(12) Patent Application Publication
(10) Pub. No.: US 2014/0118907 A1
(43) Pub. Date: May 1, 2014

(54) Dielectric Insulated Capacitor Bank

(71) Applicants: Clay Lynwood Fellers, Little Mountain, SC (US); Karl Eric Fender, Greenwood, SC (US); Gregory Earle Goff, Greenwood, SC (US); Marco James Mason, Greenwood, SC (US)

(72) Inventors: Clay Lynwood Fellers, Little Mountain, SC (US); Karl Eric Fender, Greenwood, SC (US); Gregory Earle Goff, Greenwood, SC (US); Marco James Mason, Greenwood, SC (US)

(73) Assignee: COOPER TECHNOLOGIES COMPANY, Houston, TX (US)

(21) Appl. No.: 14/053,156

(22) Filed: Oct. 14, 2013

Related U.S. Application Data
(60) Provisional application No. 61/721,077, filed on Nov. 1, 2012.

(51) Int. Cl. H05K 7/00

(52) U.S. Cl. CPC H05K 7/005
USPC 361/679.01

(57) ABSTRACT

An electrical system includes an enclosure having at least one enclosure wall forming a cavity that is environmentally sealed. The electrical system can also include a capacitor bank having at least one capacitor and at least one fuse positioned within the cavity of the enclosure. The electrical system can further include an insulating medium disposed within the cavity and in contact with at least a portion of the capacitor bank.

### CROSS-REFERENCE TO RELATED APPLICATIONS

This application claims priority under 35 U.S.C. §119 to U.S. Provisional Patent Application Ser. No. 61/721,077, titled “Dielectric Insulated Capacitor Bank” and filed on Nov. 1, 2012, the entire contents of which are hereby incorporated herein by reference.

### TECHNICAL FIELD

Embodiments described herein relate generally to capacitor banks, and more particularly to systems, methods, and devices for positioning components in a capacitor bank more closely together.

### BACKGROUND

A capacitor bank is at least one capacitor and associated components that are electrically coupled to form an electric circuit. For example, the Institute of Electrical and Electronics Engineers (IEEE) Standard 18 defines a capacitor bank as an assembly at one location of capacitors and all necessary accessories, such as switching equipment, protective equipment, and controls. Capacitor banks can serve one or more of a number of purposes. For example, a capacitor bank can be used to provide volt-amp reactive (VAR) support for an alternating current (AC) electric circuit. As another example, a capacitor bank can be used to improve power flow through an electric system to which the capacitor bank is electrically coupled. As yet another example, a capacitor bank can be used to maintain a desired voltage profile. As yet another example, a capacitor bank can be used to improve a ripple current capacity of a power supply for a direct current (DC) circuit. As still another example, a capacitor bank can be used to improve the power factor for power flowing through a corresponding electric system.

Capacitor banks often include, in addition to capacitors, other electrical devices. Such other electrical devices can include, but are not limited to, arresters, fuses, transformers, reactors, conductors, controls, relays, communication equipment, and switches. To reduce the risk of an adverse electrical condition forming between components and/or phases, a minimum amount of space separates the various components and/or phases of a capacitor bank. At times such spacing requirements can conflict with the amount of space available and/or increase the cost of material for a given application.

### SUMMARY

In general, in one aspect, the disclosure relates to an electrical system. The electrical system can include an enclosure having at least one enclosure wall forming a cavity that is environmentally sealed. The electrical system can also include a capacitor bank having at least one capacitor and at least one fuse positioned within the cavity of the enclosure, where the at least one capacitor is electrically coupled to the at least one fuse. The electrical system can further include an insulating medium disposed within the cavity and in contact with at least a portion of the capacitor bank.

In another aspect, the disclosure can generally relate to an electrical system. The electrical system can include an enclosure having at least one enclosure wall forming a cavity that is environmentally sealed. The electrical system can also include a capacitor bank having at least one capacitor and at least one arrester positioned within the cavity of the enclosure, where the at least one capacitor is electrically coupled to the at least one arrester. The electrical system can further include an insulating medium disposed within the cavity and in contact with at least a portion of the capacitor bank.

These and other aspects, objects, features, and embodiments will be apparent from the following description and the appended claims.

### BRIEF DESCRIPTION OF THE DRAWINGS

The drawings illustrate only example embodiments of dielectric insulated capacitor banks and are therefore not to be considered limiting of its scope, as dielectric insulated capacitor banks may admit to other equally effective embodiments. The elements and features shown in the drawings are not necessarily to scale, emphasis instead being placed upon clearly illustrating the principles of the example embodiments. Additionally, certain dimensions or positionings may be exaggerated to help visually convey such principles. In the drawings, reference numerals designate like or corresponding, but not necessarily identical, elements.

FIGS. 1A and 1B each show a perspective view of various portions of an electrical system that includes an open air metal enclosed capacitor bank currently known in the art.

FIGS. 2A and 2B show various views of an electrical system that includes an example dielectric insulated capacitor bank in accordance with certain example embodiments.

FIG. 3 shows a single line diagram of an electrical system that includes another example dielectric insulated capacitor bank in accordance with certain example embodiments.

### DETAILED DESCRIPTION OF EXAMPLE EMBODIMENTS

The example embodiments discussed herein are directed to systems, apparatuses, and methods of dielectric insulated capacitor banks. Such dielectric insulated capacitor banks can have one or more of a number of components that are electrically and mechanically coupled to each other. Such components of a dielectric insulated capacitor bank can include, but are not limited to, a capacitor, a control power transformer, a switch, a reactor, an arrester, a conductor, buswork, a fuse, a control relay, an instrumentation transformer, communication equipment, and a terminal connector. As described herein a dielectric for an example dielectric insulated capacitor bank excludes solely ambient air. Examples of a dielectric can include, but are not limited to, oil and a particular gas other than ambient air. In other words, while the dielectric can include de minimus amounts of air, most of the dielectric includes one or more materials other than air.

When such components are coupled together, certain standards and/or regulations are followed to address safety and/or reliability issues. For example, the International Electrotechnical Commission (IEC) and the IEEE maintain a number of standards (e.g., IEEE Standard 18-1992, IEC Standard 60-871-1, IEEE Standard 1036) for various types and/or aspects of capacitor banks. Such standards can address one or more of a number of aspects of a capacitor bank, including but not limited to a rating of the capacitor bank (e.g., in KVAR), testing of capacitors, configuration of the components of the capacitor bank, minimum required clearance of components of a capacitor bank, protection schemes, and conductor size used to electrically couple components of a capacitor bank.

Capacitors of a capacitor bank described herein are used for power distribution or, in some cases, transmission. The voltage levels associated with power distribution can be below or equal to approximately 34.5 kV, although distribution levels can reach as high as approximately 69 kV or more. The voltage levels associated with power transmission can be higher than the voltage levels associated with power distribution for a particular electrical system. In other words, the capacitors described herein can have a minimal capacitance. For example, a capacitor (or a number of series- and/or parallel-connected capacitors) included in an example capacitor bank can have a capacitance of at least approximately 0.25 microFarads (mF) per phase.

A user as described herein may be any person that is involved with installation and/or maintenance of a dielectric insulated capacitor bank. Examples of a user may include, but are not limited to, a company representative, an electrician, an engineer, a mechanic, an operator, a consultant, a contractor, and a manufacturer's representative.

Example embodiments of dielectric insulated capacitor banks will be described more fully hereinafter with reference to the accompanying drawings, in which example embodiments of dielectric insulated capacitor banks are shown. Dielectric insulated capacitor banks may, however, be embodied in many different forms and should not be construed as limited to the example embodiments set forth herein. Rather, these example embodiments are provided so that this disclosure will be thorough and complete, and will fully convey the scope of dielectric insulated capacitor banks to those of ordinary skill in the art. Like, but not necessarily the same, elements (also sometimes called components) in the various figures are denoted by like reference numerals for consistency. Terms such as “first,” “second,” “distal,” “proximal,” “left,” “right,” “front,” and “back” are used merely to distinguish one component (or part of a component) from another. Such terms are not meant to denote a preference or a particular orientation.

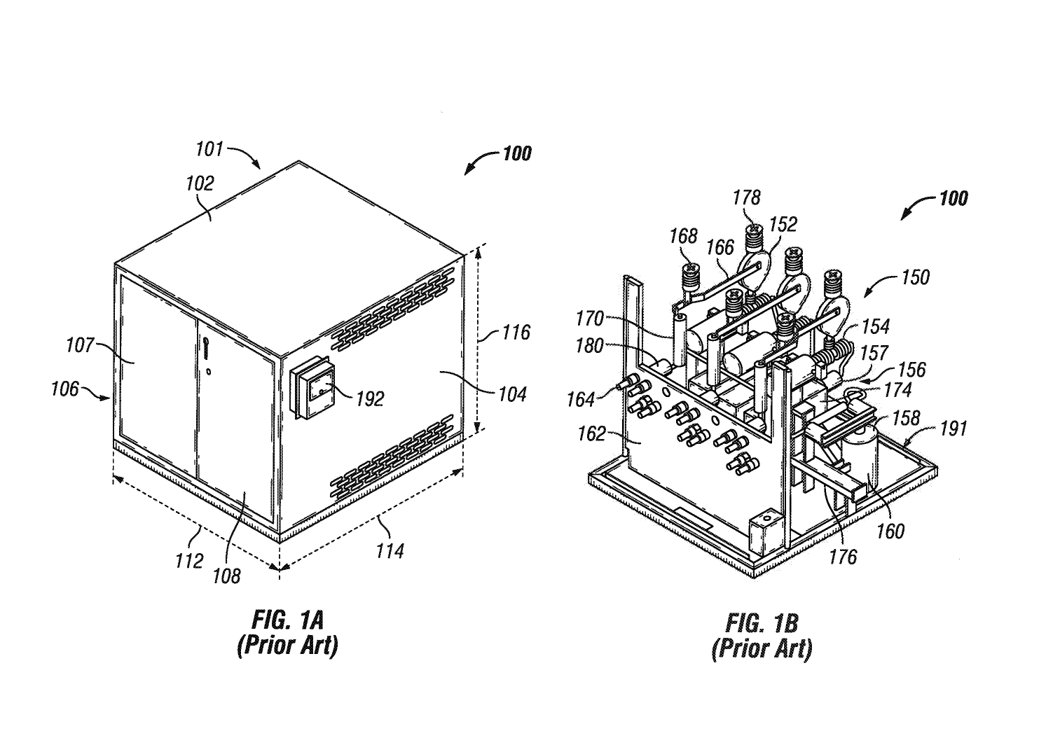

FIGS. 1A and 1B each show a perspective view of various portions of an electrical system 100 that includes open-air metal-enclosed capacitor bank 150 currently known in the art. Specifically, FIG. 1A shows a perspective view of an enclosure 101 (also called a housing 101) for a capacitor bank 150, and FIG. 1B shows a perspective view of the various components of the capacitor bank 150. In one or more embodiments, one or more of the components shown in FIGS. 1A and 1B may be omitted, repeated, and/or substituted. Accordingly, embodiments of an electrical system that includes a capacitor bank should not be considered limited to the specific arrangements of components shown in FIGS. 1A and 1B.

Referring to FIGS. 1A and 1B, the enclosure 101 of the electrical system 100 in FIG. 1A can include one or more enclosure walls. For example, as shown in FIG. 1A, the enclosure 101 can include a top surface 102, a pair of side surfaces 104, a front surface 106, and a back surface (not shown). These various enclosure walls of the enclosure 101 can define a cavity 191 or a volume of space within the enclosure 101. The enclosure 101 is shown in this example as being cubical in shape, with a height 116, a length 114, and a width 112. Alternatively, the enclosure 101 can have one or more of a number of other shapes and/or dimensions. The shape and dimensions of the enclosure 101 are sufficient to allow for adequate clearance between the inner surfaces of the enclosure 101 and the various components of the capacitor bank 150. As an example, the height 116 can be approximately 60 inches, the length 114 can be approximately 66 inches, and the width 112 can be approximately 60 inches. Thus, in this example, the volume of space (cavity 191) inside the enclosure 101 is approximately 137.5 cubic feet (ft³).

The enclosure 101 can be made of one or more of a number of suitable materials, including but not limited to stainless steel, galvanized steel, mild steel, aluminum, and various non-metals. In other words, while embodiments are described as an open air metal enclosed capacitor bank, the enclosure 101 can be made of one or more materials that are not metal. The enclosure 101 can include access from outside the enclosure 101 to the cavity 191 within the enclosure 101. For example, as shown in FIG. 1A, the front 106 of the enclosure 101 can include a pair of doors 107, 108 that open outward to access the capacitor bank 150 within the cavity 191.

The enclosure 101 can also include a control cabinet 192. In this example, the control cabinet 192 is mounted on an outer surface of one of the side surfaces 104 of the enclosure 101. The control cabinet 192 can include one or more of a number of components and/or features that allow a user to control and/or receive information with respect to the capacitor bank 150 inside the enclosure 101. The components and/or features of the control cabinet 192 can include, but are not limited to, one or more of a number of protection relays, control devices, sensors and/or indicators (e.g., for pressure, temperature inside the cavity 191), indicating lights, and radios or other methods of communication.

One of more other components and/or devices can be mounted on an exterior surface of one or more enclosure walls of the enclosure 101. For example, a temperature gauge (not shown) can be mounted on an enclosure wall to show the temperature inside the enclosure 101. In addition, or in the alternative, one or more components and/or devices can be accessible through the doors 107, 108. For example, one or more terminal connectors 164 can be disposed on a separator plate 162. The terminal connectors 164 can be configured to electrically and mechanically couple to a device (e.g., a cable) external to the enclosure 101. Such components and/or devices can be considered a part of, or separate from, the capacitor bank 150.

The capacitor bank 150 of the electrical system 100 can include a number of components that are disposed within the cavity 191 of the enclosure 101. In FIG. 1B, the components can include reactors 152 (also called inductors), switches 154, capacitor modules 156, a control power transformer 158, a separator plate 162, insulators 168, 178, busbar 166, a fuse 170, and a structural frame 176. Each capacitor module 156 can include one or more terminals 157 and a capacitor tank 174 that houses, at least, one or more capacitors. In addition, or in the alternative, one or more other components (e.g., arrester, instrument transformer) can be included in the capacitor bank 150. In certain embodiments, one of each of the components listed above is used for each phase in an AC circuit. For example, as shown in FIG. 1B, there can be three sets of capacitor modules 156, reactors 152, fuses 170, etc., where each set is electrically coupled to each phase of an AC circuit.

Some or all such components can be mounted on top of a bottom plate 160, which can include one or more features (e.g., slots, apertures) that can be used to mechanically couple the bottom plate 160 to the enclosure 101. When the enclosure 101 is mechanically coupled to the bottom plate 160, the cavity 191 inside the enclosure 101 can be protected from one or more elements, including but not limited to animals, moisture, dust, and blown objects. In addition, humans can be protected from electrically energized components that would otherwise be exposed to the ambient air. However, the enclosure 101, when mechanically coupled to the bottom plate 160, is not designed to retain certain mediums (e.g., oil, gas, liquid) other than air. Likewise, the components of the capacitor bank 150 (with the exception of the capacitor module 156, as described below) are not designed to be positioned within or operate in conditions other than air.

Each capacitor module 156 (or a portion thereof) can be positioned inside of a capacitor tank 174. The capacitor tank 174 can hold a medium (e.g., fluid) that acts as a dielectric for the capacitor module 156. In other words, such medium can be an electric insulator or dielectric that can be polarized by an applied electric field. The medium within the capacitor tank 174 can be called a dielectric medium. In certain example embodiments, the capacitor tank 174 can have at least one tank wall that forms a tank cavity, in which the dielectric medium is disposed. The capacitor tank 174 can be environmentally sealed to retain the dielectric medium and to prevent elements from outside the capacitor tank 174 from reaching inside the capacitor tank 174. Some, all, or none of a capacitor associated with a capacitor tank 174 can be positioned within the tank cavity of the capacitor tank 174.

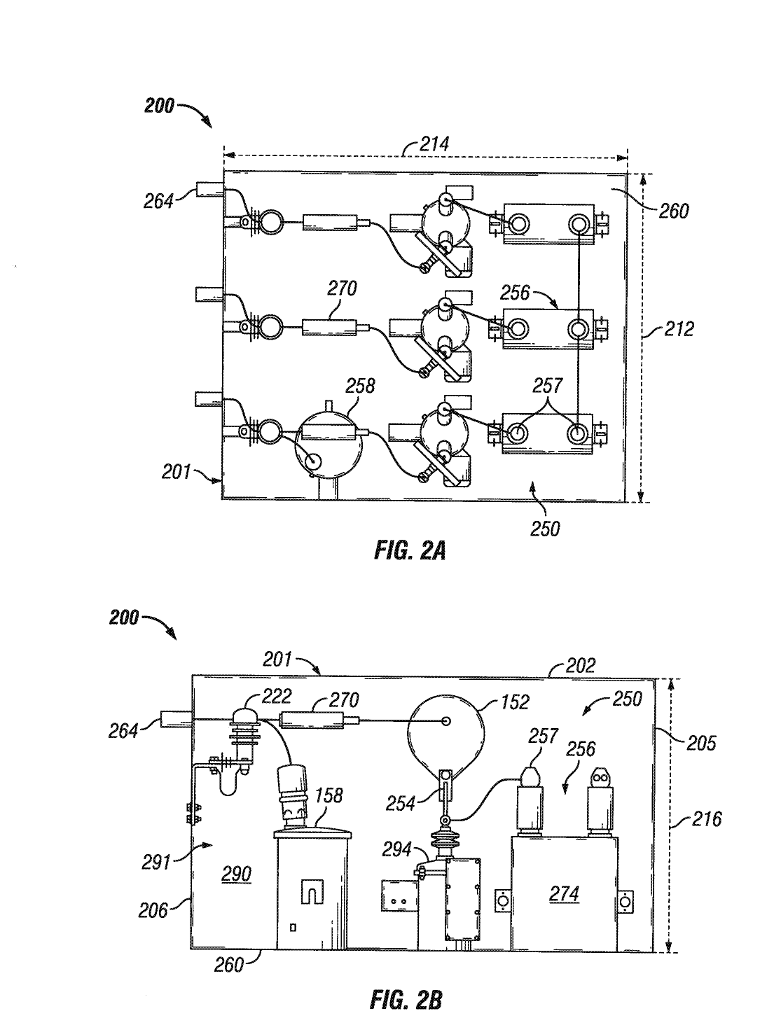

FIGS. 2A and 2B show a top view and a side view, respectively, of an example electrical system 200 that includes an example dielectric insulated capacitor bank 250 in accordance with certain example embodiments. In one or more embodiments, one or more of the features shown in FIGS. 2A and 2B may be omitted, repeated, and/or substituted. Accordingly, embodiments of an electrical system that includes a dielectric insulated capacitor bank should not be considered limited to the specific arrangements of components shown in FIGS. 2A and 2B.

Referring to FIGS. 1A-2B, the components of the capacitor bank 250 of the electrical system 200 in this case can correspond to similar components of the capacitor bank 150 of FIGS. 1A and 1B above, except as described below. The description for any component (e.g., switch 254) of FIGS. 2A and 2B not provided below can be considered substantially the same as the corresponding component (e.g., switch 154) described above with respect to the capacitor bank 150 of FIGS. 1A and 1B. The numbering scheme for the components of FIGS. 2A and 2B parallels the numbering scheme for the components of FIGS. 1A and 1B in that each component is a three digit number, where similar components between the capacitor bank 250 and the capacitor bank 150 have the identical last two digits.

The various components of the capacitor bank 250 of FIGS. 2A and 2B can be essentially the same (in function) as the components of FIG. 1B. The principal difference between the capacitor bank 250 of FIGS. 2A and 2B and the capacitor bank 150 of FIG. 1B is the footprint that each occupies. Specifically, the volume of the enclosure 101, defined by the length 114 times the width 112 times the height 116, is greater than the volume of the enclosure 201, defined by the length 214 times the width 212 times the height 216.

In certain example embodiments, the capacitor bank 250 is disposed within an enclosure 201 that is shown as being cubical in shape, with a height 216, a length 214, and a width 212. The components (e.g., capacitor, switch) of the capacitor bank 250 within the enclosure 201 can be substantially the same as the components of the capacitor bank 150 within the enclosure 101. The enclosure 201 can have one or more of a number of shapes and/or dimensions. The shape and dimensions of the enclosure 201 are sufficient to allow for adequate clearance between the inner surfaces of the enclosure 201 and the various components of the capacitor bank 250. For example, the height 216 can be approximately 36 inches, the length 214 can be approximately 60 inches, and the width 212 can be approximately 50 inches. Thus, in this example, the volume of space (also called a cavity) inside the enclosure is approximately 62.5 ft³, which is approximately one half the volume of the cavity of the enclosure 101 that houses the capacitor bank 150 of FIGS. 1A and 1B.

In certain example embodiments, the cavity 291 inside the enclosure 201, in addition to housing the capacitor bank 250 (e.g., one or more capacitors, one or more arresters 222), is filled with an insulating medium 290. The insulating medium 290 can be the same as, or different than, the dielectric medium, if any, inside the capacitor tank 274. The insulating medium 290 can be a solid (e.g., foam), a fluid (e.g., oil), and/or a gas. When disposed in the cavity 291 of the enclosure 201, the insulating medium 290 can be in contact with at least a portion of the capacitor bank 250.

In certain example embodiments, the insulating medium 290 has insulating properties that allow the components (e.g., capacitors, arresters 222, fuses 270) of the capacitor bank 250 to be positioned closer together without the risk of a short circuit, arcing, and/or any other adverse electric condition while the capacitor bank 250 is electrically operating (while power is flowing therethrough). In addition, the insulating medium 290 can have dielectric properties. As an example, the insulating medium 290 can be an oil, such as an oil used in a transformer for a similar purpose. The insulating medium 290 can be considered a part of, or separate from, the capacitor bank 250.

In certain example embodiments, the bottom plate 260 of the enclosure 201 is mounted on a pad or foundation made of cement or some similar material. The pad or foundation can be configured to ensure that the capacitor bank 250 is properly oriented (e.g., substantially horizontal) according to design specifications. The enclosure 201 can have at least one enclosure wall and have any of a number of shapes (e.g., sphere, cube, rectangle, triangle). All enclosure walls (e.g., bottom plate 260, the side wall 205, side wall 206, top plate 202) of the enclosure 201 can form a cavity 291 that is environmentally sealed. In other words, the at least one enclosure wall of the enclosure 201 are joined to each other in such a way as to minimize ingress of contaminants into the enclosure 201. In certain example embodiments, a pressure (or lack thereof, as with a vacuum) within the cavity 291 of the enclosure 201 can be controlled and maintained.

The enclosure 201 of the capacitor bank 250 can be made of one or more of a number of suitable materials, including but not limited to stainless steel, galvanized steel, mild steel, aluminum, and various non-metals. The enclosure 201 can include at least one access port (not shown) disposed on at least one enclosure wall. Such an access port can be configured to allow access from outside the enclosure 201 to the cavity 291 within the enclosure 201. In certain example embodiments, the access port would allow a user to access at least a portion of the cavity 291 to perform one or more operations with respect to the contents of the electrical system 200 that are disposed within the cavity 291. Examples of such operations can include, but are not limited to, draining/removing the dielectric medium, accessing one or more components of the capacitor bank 250 within the cavity 291, and adding/removing the insulating medium 290. Examples of the access to the cavity 291 can be a drain spout, a port hole, and/or an access door in the enclosure 201. The access can include sealing members (e.g., gaskets, o-rings) so that the environmental seal of the enclosure 201 is maintained when the access is closed.

In certain example embodiments, the capacitor module 256 of the capacitor bank 250 can include a capacitor (hidden from view by, and disposed within, the capacitor tank 274). The capacitor can be any type of power capacitor. Examples of types of capacitor include, but are not limited to, vacuum, AC oil filled, glass, and ceramic. In certain example embodiments, the capacitor module 256 does not require a capacitor tank 274 and/or a dielectric medium. For example, if the capacitor module 256 is a metalized film capacitor, the capacitor tank 274 and the dielectric medium could be eliminated. In such a case, the insulating medium 290 could act as both an insulator for the components of the capacitor bank 250 and a dielectric for the capacitor. When there is a capacitor tank 274, the capacitor tank 274 can be environmentally sealed from the cavity 291 of the enclosure 201.

Each capacitor module 256 can include one or more terminals 257 that are used to electrically couple the capacitor module 256 to another component (in this example, to the switch 254 and the instrument transformer 294) of the capacitor bank 250 and/or to a device located outside the enclosure 201. The terminals 257 can protrude through one or more surfaces of the capacitor tank 274.

By introducing the insulating medium 290 into the cavity 291, one or more of the components of the capacitor bank 250 may need to be altered from the components of the capacitor bank 150 embodied in FIG. 1B. For example, insulators on capacitors, switches, and/or transformers can be smaller with reduced terminal clearances and reduced creepage. In addition, one or more components of the capacitor bank 250 shown in FIGS. 2A and 2B can be added and/or deleted compared to the components of the capacitor bank 150 of FIG. 1B. For example, the capacitor bank 250 of FIGS. 2A and 2B can include one or more arresters 222 that can be used to allow current to flow from the fuse 270 (also part of the capacitor bank 250) to the terminal connector 264 during normal electrical operating conditions and divert a current to ground during an adverse electrical overvoltage condition. In this case, the terminal connectors 264 are mounted on the exterior of enclosure wall 206, rather than behind one or more doors of the enclosure, as shown above with respect to FIGS. 1A and 1B.

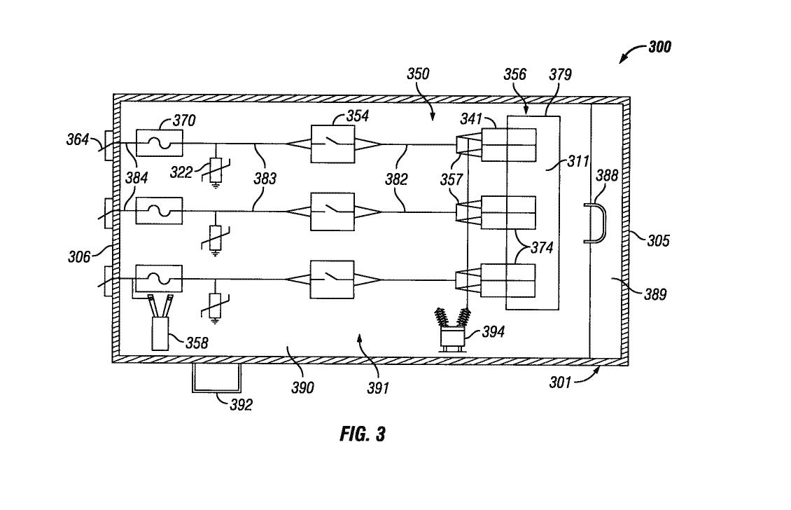

FIG. 3 shows a single line diagram of another electrical system 300 that includes an example dielectric insulated capacitor bank 350 in accordance with certain example embodiments. In one or more embodiments, one or more of the features shown in FIG. 3 may be omitted, repeated, and/or substituted. Accordingly, embodiments of an electrical system that includes a dielectric insulated capacitor bank should not be considered limited to the specific arrangements of components shown in FIG. 3.

Referring to FIGS. 1A-3, the components of the capacitor bank 350 of the electrical system 300 in this case is substantially the same as the capacitor bank 250 of FIGS. 2A and 2B above, except as described below. The description for any component (e.g., switch 354) of the capacitor bank 350 of FIG. 3 not provided below can be considered substantially the same as the corresponding component (e.g., switch 154) described above with respect to the capacitor bank 250 of FIGS. 2A and 2B. The numbering scheme for the components of FIG. 3 parallels the numbering scheme for the components of FIGS. 2A and 2B in that each component is a three digit number, where similar components between the capacitor bank 350 and the capacitor bank 250 have the identical last two digits.

The capacitor bank 350 of FIG. 3 has a few additional components and features not shown in the capacitor bank 250 of FIGS. 2A-2B. For example, the optional pressure relief device 388 shown in FIG. 3, if provided, can be disposed on the enclosure 301 and provide a channel for excess pressure that builds up within the cavity 391 to escape into the atmosphere and/or into the medium discharge chamber 389. For example, the pressure relief device 388 can be used to avoid a rupture in the enclosure 301 when an internal arc occurs between components and/or phases of the capacitor bank 350.

The pressure relief device 388 can automatically activate only when the pressure within the cavity 391 reaches a minimum threshold pressure. In addition, or in the alternative, the pressure relief device 388 can be manually adjusted to release pressure within the cavity 391 when a user manipulates the pressure relief device 388 in a certain manner. Excess pressure can develop within the cavity 391 in one or more of a number of ways, including but not limited to an increase in temperature within the cavity 391, an explosion, a fault, and a failure of a component within the cavity 391.

In certain example embodiments, the enclosure 301 can include a medium discharge chamber 389. The medium discharge chamber 389 can be a separate chamber within the cavity 391, or located adjacent to the cavity 391, of the enclosure 301. The medium discharge chamber 389 can be configured to hold excess insulating medium 390 and/or dielectric medium. The medium discharge chamber 389 can receive insulating medium 390 and/or dielectric medium 311 based on one or more of a number of operating conditions, including but not limited to an overpressure situation, an overtemperature situation, an explosion, a fault, and a manual operation by a user. In such a case, the medium discharge chamber 389 can receive the insulating medium 390 and/or the dielectric medium 311 displaced from the cavity 391 through the pressure relief device 388. The medium discharge chamber 389 can be environmentally separated from the cavity 391 within the enclosure 301 such that the medium discharge chamber 389 can be accessible while one or more of the components of the capacitor bank 350 are operating.

The instrument transformer 394 (also called a sensing device) can be any device that steps a voltage or current up or down from a node inside of the capacitor bank 350. The example instrument transformer 394 can be coupled (e.g., electrically, magnetically, communicably) to at least one capacitor module 356 (or portion thereof, such as a terminal 357 electrically coupled to the capacitor) and/or one or more other components of the capacitor bank 350. The instrument transformer 394 can be coupled to a component of the capacitor bank 350 using a conductor, a busbar, a terminal, or some other connecting means. For example, the instrument transformer 394 can be electromagnetically coupled to a conductor by surrounding the conductor. In such a case, the instrument transformer 394 can clamp around and/or encircle the conductor. In addition, or in the alternative, the instrument transformer 394 can be electrically (or communicably, if using wireless technology) coupled to (capable of sending and receiving signals with respect to) a sensor and/or relay in the control cabinet 392. In such a case, the instrument transformer 394 can clamp around and/or encircle the conductor.

The instrument transformer 394 can have one or more leads that carry the voltage or current from the instrument transformer 394 to a relay, sensor, measuring device, and/or other device (generally called a receiving device). The leads can be a form of conductor, as described above. The representation of the operating parameter (e.g., current, voltage) can be an electrical signal (e.g., analog signal, digital signal), an electro-mechanical signal, and/or any other suitable signal. The representation of the operating parameter can be a fractional amount of (proportionately smaller than) the operating parameter. The difference between the operating parameter and the representation of the operating parameter can be defined by a ratio. In one example embodiment, the representation of the operating parameter is sent by the instrument transformer 394 to the receiving device.

In certain example embodiments, the instrument transformer 394 includes a primary winding and a secondary winding. The primary winding and the secondary winding typically have a known ratio (e.g., 7200:120). As a result, in such a case, the secondary winding, to which the leads are electrically coupled, generates a representation of the operating parameter that is 60 times less than the operating parameter.

The control cabinet 392 allows interaction between a user and the capacitor bank 350. The control cabinet 392 can include one or more components (e.g., an unbalance relay, a control switch, sensors and/or indicators (e.g., for pressure, temperature inside the cavity), indicating lights) that are communicably coupled to one or more components (e.g., instrument transformer 394) of the capacitor bank 350 located inside the cavity 391. The control cabinet 392 can be a stand-alone device. Alternatively, the control cabinet 392 can be part of a control system and/or any other suitable device or system. The control cabinet 392 can be disposed on an outer surface of an enclosure wall of the enclosure 301. The communicable coupling can be accomplished using wireless and/or wired technologies.

As discussed above, the components and/or configuration of a capacitor bank can vary using example embodiments described herein. As shown in FIG. 3, the capacitor bank 350 includes three capacitor modules 356, three switches 354, three arresters 322, three fuses 370, one instrument transformer 394, one control power transformer 358, and a number of conductors (e.g., conductors 382, conductors 383, conductors 384). The three capacitor module 356 in this case share a single mounting frame 379. Each capacitor of the capacitor module 356 can have its own capacitor tank 374 filled with a dielectric medium 311. Each capacitor tank 374 can be environmentally sealed. The three (or more) capacitors 341, one for each capacitor module 356, can be mechanically coupled to the mounting frame 379. There is a terminal 357 disposed at the end of each capacitor 341.

In this example, the instrument transformer 394 (and more specifically, the primary bushing of the instrument transformer 394) is electrically coupled to a neutral of the capacitor circuit. The secondary of the instrument transformer 394 can be electrically coupled to a protective device (e.g., an unbalance relay). In certain example embodiments, the protective device can be electrically coupled to another component (e.g., one or more switches 354) of the capacitor bank 350 and cause that component to open when a capacitor fault occurs. One or more conductors 382 can be electrically and mechanically coupled to the terminal 357 and a switch 354. Thus, each switch 354 is also positioned within the cavity 391 and is electrically coupled to a capacitor 341. Each switch 354 of the capacitor bank 350 can be electrically and mechanically coupled to an arrester 322 and to an fuse 370, each within the cavity 391 of the enclosure 301. Further, each fuse 370 of the capacitor bank 350 can be electrically and mechanically coupled to a terminal connector 364, positioned outside the cavity 391 of the enclosure 301, by a conductor 384 (also called an incoming bus 384). In this example, the terminal connector 364 traverses an enclosure wall 306 with the exposed end of the terminal connector 364 positioned outside the enclosure 301.

In addition, the control power transformer 358 can be coupled (e.g., electromagnetically) to one or more of the fuses 370. One or more of a number of other components can be included in the capacitor bank 350. For example, a reactor (not shown in FIG. 3, but described above with respect to FIG. 1B) can be positioned within the cavity 391 and placed electrically in series with one or more other components of the capacitor bank 350.

Example dielectric insulated capacitor banks allow for one or more capacitor banks to be inserted into a region of space that is significantly smaller than currently possible with air insulation designed in accordance with industry standards and regulations. Specifically, immersing the components of the capacitor bank in the example insulating medium allows such components to be positioned closer to each other without compromising safety or electrical integrity.

Example dielectric insulated capacitor banks can be used in underground applications and/or at a surface (e.g., ground, cement pad, utility vault). Example dielectric insulated capacitor banks can also be mounted on a pole or tower, although some modifications may be made in case of leakage of the insulating medium 290 through the enclosure 201. Example dielectric insulated capacitor banks can be used in cases where the amount of space into which to position a capacitor bank is limited. Example dielectric insulated capacitor banks can also be used when visual obstruction by the capacitor bank is prohibited. Example dielectric insulated capacitor banks can further be used when environmental aesthetics with respect to the capacitor bank are required. Example dielectric insulated capacitor banks can also be used when inhibiting public access to the components of the capacitor bank is required or necessary. Example dielectric insulated capacitor banks can also deter vandalism and/or intrusion by animals and other natural elements.

Accordingly, many modifications and other embodiments set forth herein will come to mind to one skilled in the art to which dielectric insulated capacitor banks pertain having the benefit of the teachings presented in the foregoing descriptions and the associated drawings. Therefore, it is to be understood that dielectric insulated capacitor banks are not to be limited to the specific embodiments disclosed and that modifications and other embodiments are intended to be included within the scope of this application. Although specific terms are employed herein, they are used in a generic and descriptive sense only and not for purposes of limitation.

What is claimed is:

1. An electrical system, comprising:
an enclosure comprising at least one enclosure wall forming a cavity that is environmentally sealed;
a capacitor bank comprising at least one capacitor and at least one fuse positioned within the cavity of the enclosure, wherein the at least one capacitor is electrically coupled to the at least one fuse; and
an insulating medium disposed within the cavity and in contact with at least a portion of the capacitor bank.

2. The electrical system of claim 1, wherein the enclosure further comprises an access port disposed in the at least one enclosure wall, wherein the access port is configured to allow access to the cavity from outside the enclosure.

3. The electrical system of claim 1, further comprising:
a pressure relief device mechanically disposed on the at least one enclosure wall.

4. The electrical system of claim 3, wherein the enclosure further comprises a medium discharge chamber positioned adjacent to the cavity, wherein the medium discharge chamber is environmentally separated from the cavity, and wherein the medium discharge chamber is configured to receive insulating medium displaced from the cavity through the pressure relief device.

5. The electrical system of claim 1, wherein the capacitor bank further comprises a capacitor tank positioned within the cavity and comprising at least one tank wall forming a tank cavity, wherein at least a portion of the at least one capacitor is positioned within the tank cavity.

6. The electrical system of claim 5, wherein the capacitor bank further comprises a dielectric medium disposed in the tank cavity.

7. The electrical system of claim 5, wherein the tank cavity is environmentally sealed from the cavity of the enclosure.

8. The electrical system of claim 1, wherein the at least one capacitor comprises three capacitors.

9. The electrical system of claim 8, wherein the insulating medium comprises insulating properties that allow the three capacitors to be positioned a distance from each other without a risk of an adverse electric condition while power flows through the three capacitors.

10. The electrical system of claim 9, wherein the insulating medium is an oil.

11. The electrical system of claim 9, wherein the insulating medium is a foam.

12. The electrical system of claim 1, further comprising:
a control cabinet disposed on the at least one enclosure wall, wherein the control cabinet comprises at least one component that is communicably coupled to the capacitor bank.

13. The electrical system of claim 1, wherein the capacitor bank further comprises an instrument transformer positioned within the cavity and electrically coupled to the at least one capacitor.

14. The electrical system of claim 1, wherein the capacitor bank further comprises at least one reactor positioned within the cavity and electrically coupled to the at least one fuse.

15. The electrical system of claim 1, wherein the capacitor bank further comprises at least one arrester positioned within the cavity and electrically coupled to the at least one fuse.

16. The electrical system of claim 15, wherein the capacitor bank further comprises at least one switch positioned within the cavity and electrically coupled to the at least one fuse and the at least one arrester.

17. The electrical system of claim 16, further comprising:
at least one terminal connector positioned outside the cavity and electrically coupled to the at least one fuse.

18. The electrical system of claim 17, wherein the capacitor bank further comprises a control power transformer positioned within the cavity and electromagnetically coupled to the at least one fuse.

19. The electrical system of claim 18, wherein the at least one capacitor has a capacitance of at least 0.25 microFarads.

20. An electrical system, comprising:
an enclosure comprising at least one enclosure wall forming a cavity that is environmentally sealed;
a capacitor bank comprising at least one capacitor and at least one arrester positioned within the cavity of the enclosure, wherein the at least one capacitor is electrically coupled to the at least one arrester; and
an insulating medium disposed within the cavity and in contact with at least a portion of the capacitor bank.
